(19) United States
(12) Patent Application Publication
(10) Pub. No.: US 2009/0224243 A1
(43) Pub. Date: Sep. 10, 2009

(54) Spontaneous Growth Of Nanostructures On Non-single Crystalline Surfaces

(76) Inventors: Nobuhiko Kobayashi, Sunnyvale, CA (US); Shih-Yuan Wang, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/243,139

(22) Filed: Oct. 1, 2008

Related U.S. Application Data
(60) Provisional application No. 61/034,589, filed on Mar. 7, 2008.

(51) Int. Cl. H01L 31/036; H01L 21/20; H01L 21/44

(52) U.S. Cl. 257/49; 438/478; 438/682; 257/E29.079

(57) ABSTRACT

A method of forming nanostructures using catalyst-free epitaxial growth includes depositing a first layer of a non-single crystalline material on a support structure; heating the support structure and the first layer such that a combined layer is formed; and growing a nanostructure on the combined layer. A hetero-crystalline includes a support structure; a first layer of non-single crystalline material deposited on the support structure and combined with the support structure or a second layer to form a combined layer; and a nanostructure of a single crystalline material grown on the combined layer.

### CROSS-REFERENCE TO RELATED APPLICATION

The present application claims priority from provisional application Ser. No. 61/034,589, filed Mar. 7, 2008, the contents of which are incorporated herein by reference in their entirety.

### BACKGROUND

Nanostructures have a wide range of applications which leverage the increased surface area and quantum effects of nanometer sized systems. The high surface-area-to-volume ratio of nanostructures can play an important role in many applications, such as facilitating chemical reactions in fuel cells and batteries and serving as chemical and biological sensors. Nanostructures also exhibit quantum effects which can significantly alter their optical, magnetic, or electrical properties. Examples of quantum structures include quasi-zero-dimensional structures (e.g., quantum dots) and quasi-one-dimensional structures (e.g., nanorods, nanowires, and nanotubes).

In some circumstances it can be desirable to grow or deposit nanostructures directly on a surface. By growing or binding nanostructures onto a macro scale substrate, the nanostructures can be incorporated into larger scale structures. These large scale structures could include objects such as computer processors, memory, analysis chips, fabrics, displays, and other applications. These nanostructures could perform a variety of functions, including, but not limited to, generating electromagnetic radiation (such as lasers, light emitting diodes, antennas, and the like), detecting or absorbing electromagnetic radiation (such as solar cells, photo detectors, etc.), forming electronic junctions (such a p-n junctions), increasing the surface area in electrostatic applications (such a capacitor), mechanical operations (such as filtering, switching, supporting, altering the strength or surface properties of the substrate, etc.), biological functions (such as serving as a binding site for a particular molecule), or chemical functions (such as in a battery, fuel cell, or catalytic converter).

Typically, a catalyst is used to facilitate the growth of a nanostructure, in particular quasi-one-dimensional nanostructures, on a substrate surface. However, certain catalyst materials, such as gold, have deleterious effects on the reliability and performance of some semiconductor devices, particularly those comprising silicon. Removing the catalyst material from the nanostructures without damaging the nanostructures after catalytic growth is not always feasible. Therefore, using catalyst-free growth processes to form nanometer-scale structures spontaneously on substrate surfaces can be advantageous.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1A is a cross-sectional diagram of an illustrative substrate configured to support the spontaneous epitaxial growth of nanostructures, according to one embodiment of the principles described herein.

FIG. 1B is a cross-sectional diagram of an illustrative substrate with a number of nanostructures spontaneously and epitaxially grown on the upper surface of the substrate, according to one embodiment of the principles described herein.

FIG. 2 is an illustrative scanning electron microscope measurement of nanostructures that were spontaneously grown on a substrate, according to one embodiment of the principles described herein.

FIG. 3 is a flowchart showing an illustrative method for preparing and growing nanostructures spontaneously on a substrate, according to one embodiment of the principles described herein.

FIG. 4 is a flowchart showing an illustrative method for preparing and growing nanostructures spontaneously on a glass or amorphous substrate, according to one embodiment of the principles described herein.

FIG. 5 is a flowchart showing an illustrative method for preparing and growing nanostructures spontaneously on a stainless steel or other metal substrate, according to one embodiment of the principles described herein.

Throughout the drawings, identical reference numbers designate similar, but not necessarily identical, elements.

### DETAILED DESCRIPTION

A variety of nanostructures can be grown on a substrate. By way of example and not limitation, nanostructures grown on a substrate may include nanowires, nanotubes, and nanodots. A nanowire is a single crystalline structure typically characterized as a cylinder having two spatial dimensions that represent its diameter and its length. Because a nanowire diameter is typically much smaller than its length, a nanowire is often referred to as a quasi-one dimensional structure. According on one exemplary embodiment, a nanowire may have a diameter of 1-1000 nanometers and an axial length of 10 to 1000 micrometers. A nanowire typically has a solid cross-section. The relatively large length of nanowires facilitates electron wavefunctions along that dimension or length, while electron energy levels are quantized along the other two spatial dimensions in which the width or diameter of the nanowire exists. A nanowire may also be referred to a whisker or a nanoneedle.

In some embodiments, the nanostructure comprises a nanotube. Like a nanowire, a nanotube is also characterized as having two spatial dimensions that are much smaller than a third spatial dimension or direction. Unlike the nanowire, however, the nanotube has a hollow cross-section.

In other embodiments, the nanostructure may comprise a nanodot (i.e., a quantum dot). A nanodot is a single crystalline structure in which all three spatial dimensions are on the order of 1 to 100 nanometers. In a quantum dot, electron wavefunctions are confined and, as a result the associated energy levels, are quantized in all three spatial dimensions.

As mentioned above, metal catalyzed nanostructures can perform poorly in many applications, particularly those involving semiconductors. In metal catalyzed growth of nanostructures, numerous metal clusters that are present on a surface act as nucleation sites for, and accelerate the growth of, the nanostructures. Subsequent removal of the metal catalyst clusters that are then integral to the nanostructure can be very difficult. Additionally, stray catalyst materials can be homogeneously incorporated throughout the nanostructures and can also be difficult remove.

For instance, noble metals (e.g., gold) or other transition metals (e.g., Ti) can be used as catalyst and nucleation sites for the growth of a nanowire. In the growth of nanowires using a metal catalyst, the diameter of the nanowires is limited by the diameter of the metal catalyst duster. In other Words, the diameter of the nanowires cannot be actively controlled. In contrast, in the growth of nanowires without a metal catalyst, the diameter of the nanowires can be controlled by growth conditions such as growth temperature.

As the nanowire grows, the metal catalyst duster remains, by the definition of a catalyst, on the tip of the nanowires. However, there is a finite probability of gold or other metal catalyst being incorporated within the nanowire during growth. When this occurs, electrical and optical properties of the nanowires contaminated with metal catalysts can be undesirably impacted. For example, the gold or other catalyst metals reduce minority charge carrier lifetimes by creating deep level and mid-level trapping within the bandgap of the nanowire. By shortening the minority carrier lifetime in semiconductor nanowires, metal catalyst material incorporated within a nanostructure causes the semiconductor nanostructure to exhibit unstable electrical transport properties or otherwise severely reduces electrical and optical functionality.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Throughout the present specification and appended claims, the term “non-single crystalline material” is used. This term is defined as follows. The arrangement of atoms within a solid can range from a high degree of order in single crystalline material to a low degree of order in an amorphous material. A single crystalline material has a crystal lattice that is essentially continuous on a millimeter scale. In contrast, a non-single crystalline material can be defined as having short range atomic ordering associated with the various crystallites that make up the material. The crystallites are multiple, small regions of crystalline material dispersed throughout the non-single crystalline material. For example, a non-single crystalline material may have short range atomic ordering ranging in extent from 1 nanometer to about 100 microns. The crystallite dispersion may range from clusters or groups of individual crystallites to discrete individual crystallites.

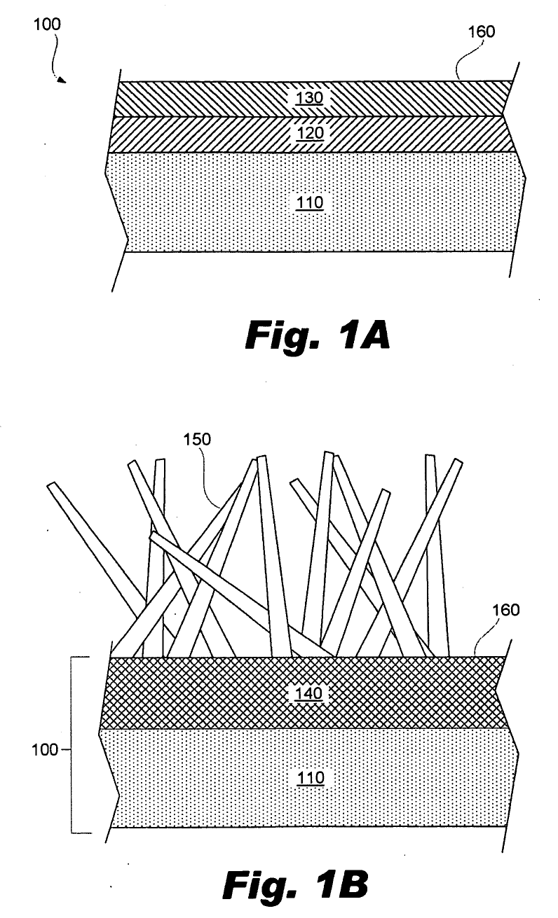

FIG. 1A shows a substrate (100) prior to the growth of nanostructures on the substrate's upper surface (160). According to one illustrative embodiment, the substrate may be comprised of a support material (110), a first layer (120) and a non-single crystalline second layer (130). The top of the non-single crystalline second layer (130) forms the upper surface (160).

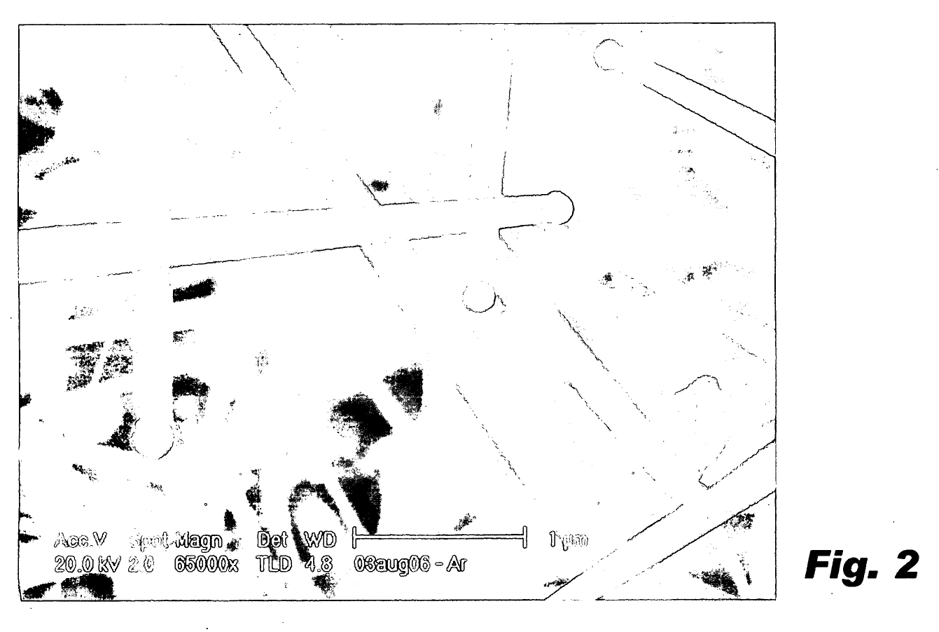

The actual and comparative dimensions of elements, components, and layers within the FIGS. 1A, 1B and 2 have been altered for illustration purposes. For example, the thickness of the layers (120, 130) would be on the order of nanometers. However, to facilitate this explanation, the thickness of the layers (120, 130) has been significantly exaggerated in the illustrations.

The support material (110) may be comprised of a variety of materials including but not limited to glass, ceramic, metal (including stainless steel), plastic, polymer, dielectric, a semiconductor and/or any combination of these materials. In various embodiments, the support material (110) may be rigid, semi rigid, or more flexible depending on the specific application of the nanostructure device. The support material (110) may have regular or irregular geometrical patterns on its surface. In one illustrative embodiment, a semiconductor support material may be used. The semiconductor support material may have a single crystalline structure, an amorphous structure, or in non-single crystalline structure (i.e., having crystallites).

The support material (110) is coated with a first layer (120). The first layer (120) may be comprised of a variety of materials including, but not limited, to group IV semiconductors (germanium and germanium alloys, silicon and silicon alloys), group III-V compound semiconductors, group II-VI compound semiconductors, noble metals, transition metals, and metal alloys. Specific illustrative examples of materials which could be included in the first layer (120) include zinc oxide, titanium, platinum, tungsten, and stainless steel. According to one illustrative embodiment, the first layer (120) may comprise a metal film between 10 and 500 nanometers in thickness.

A second layer (130) of non-single crystalline material is deposited on top of the first layer (120). The second layer (130) may include, but is not limited to, one of an electrical insulator, a semiconductor, and an electrical conductor. In some embodiments, the material of the non-single crystalline layer is a semiconductor that includes one or more of a semiconductor, a compound semiconductor, and a semiconductor alloy. The semiconductor material may include, but is not limited to, one or more semiconductors from Group IV, a compound semiconductor selected from Group II-V and a compound semiconductor selected from Group II-VI. In some embodiments, the material of the non-single crystalline layer is an electrical conductor, including one or more of a metal, a metal alloy, and a metal compound. In some embodiments, the material of the non-single crystalline layer (130) is an insulator material including, but not limited to, one or more of an oxide, a nitride, and a carbide of a semiconductor or a metal (e.g., silicon dioxide, quartz and alumina). In one illustrative embodiment, the second layer (130) may be a microcrystalline or nano-crystalline silicon layer deposited between 10 and 300 nanometers thick.

According to one exemplary embodiment, the first layer (120) is a metal or transition metal and the non-single crystalline second layer (130) is silicon or a silicon compound. For some applications, the deposition order of the two layers is flexible. For example, the order of the layers could be reversed by depositing the second layer (130) on the support material (110) then depositing the metal or transition metal layer (120) on top of the non-single crystalline second layer (130). However, in some circumstances it can be desirable to deposit the metal layer (120) on the support material (110) and then cover the upper surface of the metal layer (120) with the non-single crystalline second layer (130) to minimize undesirable oxidization of the metal layer (120).

A variety of methods can be used to deposit the first layer. (120) and non-single crystalline second layer (130) onto the substrate. In some embodiments, the layers could be deposited using a chemical vapor deposition (CVD) process, such as plasma enhanced CVD (PECVD). Other methods of deposition include, but are not limited to, physical vapor deposition, such as sputtering vacuum evaporation. In other embodiments, a solid film of non-crystal material may be adhered to the surface of the underlying layer or may be printed on the surface of the underlying layer using a printing technology, such as inkjet printing. For instance, a solution containing metallic or non-single crystalline particles can be applied as the second layer (130) by inkjet printing or other fluid deposition technique on the support material (110).

One example of a non-single crystalline material is nanocrystalline silicon (nc-Si) or microcrystalline silicon (μc-Si). The non-single crystalline material may be characterized as a layer having an amorphous phase or matrix within which small grains of crystallized silicon are embedded. In contrast, polycrystalline silicon (poly-Si) consists only of crystalline silicon grains, separated by grain boundaries.

Crystalline silicon is formed by organizing four-fold, tetrahedrally coordinated bonds to four neighboring silicon atoms. In crystalline silicon, this tetrahedral coordination is continued over a large range, forming a well ordered lattice (crystal). In non-single crystalline and amorphous silicon, this long range order is not present. Instead the silicon atoms form a random network. Due to the disordered nature of the material, some atoms have dangling bonds. These dangling bonds are physically and chemically active (e.g., unsaturated) defects which can cause undesirable electrical and optical behavior. Non-single crystalline silicon and amorphous silicon can be passivated by bonding hydrogen to saturate the dangling bonds. The resulting material is hydrogenated amorphous silicon (a-Si:H) or hydrogenated microcrystalline silicon (μc-Si:H).

One of the main advantages of the amorphous and non-single crystalline silicon is that it can be deposited over large areas by plasma enhanced chemical vapor deposition on a variety of surfaces at relatively low temperatures, as opposed to crystalline silicon wafers which are sliced from bulk mono-crystalline forms. Amorphous and non-single crystalline silicon can be used as an active layer in thin film transistors and to produce large area photovoltaic solar cells. Amorphous and non-single crystalline silicon can also be deposited at a very low temperatures (as low as 75° C.) which allows for deposition onto plastic substrates.

FIG. 1B is a cross-sectional diagram of an illustrative substrate (100) with nanostructures (150) that have been spontaneously grown on the upper surface (160) of the substrate (100).

During the growth process, the temperature of the substrate (100) is raised sufficiently that the first layer (120, FIG. 1A) and non-single crystalline second layer (130, FIG. 1B) interact to form a combined layer (140). In one illustrative embodiment, the combined layer (140) is a silicide. The elevated temperature during the growth process allows for a silicide annealing process to occur.

To create a silicide, the first layer (120), typically of a transition metal, reacts with the second layer (130), typically a silicon-based material, to form the silicide compound. The result is a low-resistance, transition metal silicide. By way of example and not limitation, the silicide may be platinum silicide (PtSi), titanium silicide (TiSi₂), or tungsten silicide (WSi₂).

Although the combined layer (140) is generally characterized as having a substantially homogenous composition, there is no requirement for a homogenous composition. For example, discontinuities and non-homogeneous regions could occur within the combined layer (140). The discontinuities and non-homogeneous regions could occur for a variety of reasons, including material impurities, low temperature processes, and/or short processing times during the growth process

Growing nanostructures (150) on the prepared substrate (100) using catalyst-free epitaxial growth comprises controlling growth conditions of the nanostructure to form a nanostructure integral to a crystallite of the combined layer (140) on the upper surface (160) of the substrate (100). For example, nanostructure growth could be initiated in a CVD reaction chamber using a gas mixture of a nanostructure source material that is introduced into the chamber at a growth temperature. The constituent molecules leave the gas and bind to an exposed face of a crystallite embedded in the upper surface of the combined layer (160). The constituent molecules self assemble to form the nanostructure.

The geometry and growth of the nanostructure can be controlled to some degree by altering the epitaxial environment. In some embodiments, controlling growth conditions comprises tuning growth temperature and gas composition. For example, if a source gas ‘A’ and a source gas ‘B’ are used to grow ‘AB’ nanostructures, the proportions of gas ‘A’ and gas ‘B’ within the mixture can be altered.

During epitaxial growth, nanowires, for example, may grow along a certain preferential direction parallel to the crystal direction of a respective crystallite seed. The crystallites of the combined layer are randomly oriented and are randomly located in the first layer. As a result of the random orientation of the crystallites, nanowires will grow in random directions from the first layer surface. Moreover, not all crystallites near the surface of the first layer will nucleate growth of a nanostructure. Consequently, the growth of the nanostructure in any particular location on the surface of the first layer is also essentially random.

In other embodiments, the nanostructures may form spontaneously on the combined layer without a crystallite seed. Such structures arise from self-organized growth driven by strain associated with the difference in lattice constants between various materials and structures within the combined layer (140).

In some embodiments, growing a nanostructure comprises spontaneously growing a nanowire or a nanotube integral to a crystallite in the combined layer (140) using catalyst-free epitaxial growth. In other embodiments, growing a nanostructure comprises growing a nanodot integral to a crystallite in the combined layer (140) using the catalyst-free epitaxial growth. To grow a nanodot, the epitaxial growth is started then almost immediately stopped.

In still other embodiments, growing a nanostructure comprises growing a nanodot integral to the crystallite in the combined layer (140) using catalyst-free, spontaneous growth; and further growing a single crystalline nanowire from the nanodot. The grown nanodot provides a seed that facilitates the growth of the nanowire. The nanowire is effectively integral to the nanodot and the nanodot is integral to the combined layer. The nanostructure effectively comprises both a nanodot and a nanowire.

In the embodiments of the nanostructure that comprises both a nanodot and a nanowire, the semiconductor material of the single crystalline nanodot may be the same as or different from the semiconductor material of the single crystalline nanowire, depending on the embodiment. Moreover, in some of these embodiments, the semiconductor material of the growing nanowire can be changed during growth such that the semiconductor material is different in segments along the axial length of the nanowire.

FIG. 2 is a scanning electron microscope measurement of nanostructures spontaneously grown on a substrate according to an embodiment of the principles disclosed herein. The nanowires are comprised of indium phosphate (InP). The nanowires were grown on a microcrystalline hydrogenated silicon layer overlying a stainless steel substrate. FIG. 2 illustrates both the overall organization of the nanowires on the substrate as well as the geometry of individual nanowires. According to one exemplary embodiment, the diameter of the nanowires ranges from 1 to 1000 nanometers and the length of the nanowires ranges from 1 to 10 microns.

As mentioned above, the nanowires may nucleate and grow on crystallites that are randomly oriented and randomly located in the non-single crystalline surface. The direction of nanowire growth is dependent on the orientation and characteristics of the crystal face of the crystallite to which the base of the nanowire is attached. Because the crystallites in this embodiment are randomly oriented and randomly located within the non-single crystalline surface, the nanowires tend to grow from apparently random locations on the surface and grow in apparently random directions. These random features are useful in certain applications such as devices that detect light.

The nanostructures may also spontaneously form on the non-single crystalline surface by nucleating on surface discontinuities. A variety of variables may influence the nucleation sites of the nanostructures including material properties of the non-single crystalline surface and nanostructure, temperatures, pressures, geometry, and other factors. Similarly, the orientation and other geometric parameters of the nanostructures can be influenced by a variety of factors.

In some embodiments, the growth parameters of the nanowire are controlled to adjust the shape of the resulting wire. For example, a nanowire can have a symmetrical columnar shape along its axial length. In another example, the nanowire can have an asymmetrical shape, such as a tapered or pyramidal shape, where the nanowire is wider at the end that is anchored to the non-single crystalline surface and narrower at the opposite end. This taper angle can be achieved by manipulating one or more of temperature, time, and the ratio of gases that are introduced into the deposition chamber. For example, the precursor gas may regulate growth rates on different crystallographic planes, which directly control the three-dimensional features of nanostructures.

A ball or globule can be observed at the tip of a number of nanowires illustrated within FIG. 2. The balls on the end of the nanowires have been determined to be indium. The indium contained within the balls is progressively incorporated into the nanowire structure by the diffusion of phosphorus into the indium. As indium is consumed from the ball and integrated into the nanowire, additional indium is added to the ball through the condensation of indium from the precursor gas, suggesting indium phosphide nanowires are grown spontaneously by being mediated with one of their constituents (i.e., indium in this case) without a catalyst.

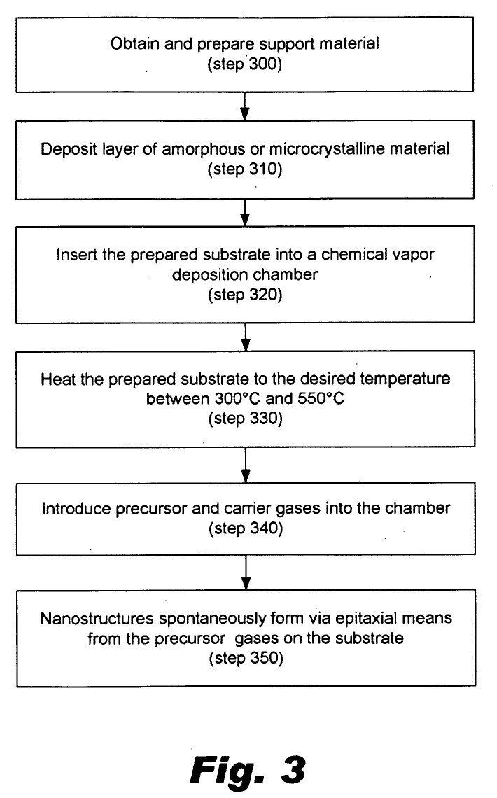

FIG. 3 shows a flowchart showing one illustrative method for preparing a substrate and creating a spontaneous growth of nanoscale structures on the substrate. In a first step, a support material is obtained and prepared (step 300). As mentioned above, the support material may be selected from a variety of materials. The preparation of the support material can vary according to the material properties of the support material, the desired end product, and other factors. For example, if a plastic support material is selected, the plastic could be prepared by machining or otherwise forming the substrate into a desired geometry. A variety of surface treatments could also be used to render the plastic support material amenable to the subsequent steps.

For nonmetallic support material, it may be desirable to deposit a first metal layer as part of the preparation process. For metallic support material such as stainless steel, the deposition of a first metallic layer may be unnecessary.

A layer of amorphous or microcrystalline material is then deposited on the substrate (step 310). According to one illustrative embodiment, the amorphous or microcrystalline material may be hydrogenated amorphous silicon or hydrogenated microcrystalline silicon. As discussed above, this deposition could be accomplished via a number of processes, including, but not limited to chemical vapor deposition (CVD) and physical vapor deposition. The deposition sequence of (step 300) and (step 310) can be reversed.

The prepared substrate is then inserted into a chemical vapor deposition chamber (step 320) or a separated reaction chamber different from a deposition chamber in which nanostructures are formed. The substrate is heated to the desired temperature, typically between 150° C. and 1000° C. (step 330). The temperature need not be a constant temperature but can be varied to accomplish the desired result. For example, the initial temperature may be higher than subsequent temperatures to facilitate the formation of a silicide layer from the combination of a metallic layer and a silicon layer.

The precursor gases are then introduced into the chamber (step 340). According to one exemplary embodiment, hydrogen gas is also introduced into the deposition chamber. The hydrogen gas is used to combine with dangling bonds to passivate the material, providing for greater electron mobility and reducing the effects of discontinuities within the non-single crystalline layer.

The nanostructures then spontaneously form from the precursor gases by nucleating and growing on the exposed surfaces of the substrate (step 350). As described above, nanostructures may seed on crystallites or other features of the silicide layer.

The steps above are one illustrative method for the epitaxial growth of nanostructures without the use of a catalyst. The steps may be reordered, combined, or additional steps may be used as best suits a particular application. For example, the steps of heating the prepared substrate (step 330) and the introduction of precursor and carrier gases into the chamber (step 340) may be performed simultaneously.

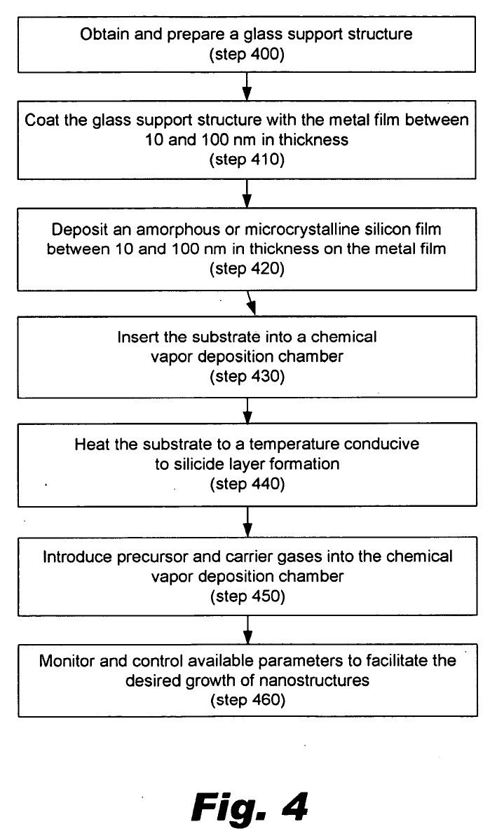

FIG. 4 is a flowchart showing an illustrative method for preparing and growing nanostructures using a catalyst free epitaxial process on a glass or amorphous structure. In a first step, a glass support structure is obtained and prepared (step 400).

The glass substrate is then coated with a metallic film between 10-300 nanometers in thickness (step 410). On top of the metallic film, an amorphous or microcrystalline silicon film is deposited on the metallic film (step 420). According to one exemplary embodiment, the amorphous or microcrystalline silicon film also has a thickness between 10-500 nanometers.

During the deposition of the silicon film, hydrogen atoms can be chemically bonded to at least a portion of the silicon atoms that are not otherwise bonded. As discussed above, this passivates or hydrogenates the silicon layer.

The substrate is then inserted into a chemical vapor deposition chamber (step 430). The substrate temperature is then increased to a level that is conducive to the formation of a silicide layer (step 440). The silicide layer is formed by diffusive chemical reaction of the metal layer and the silicon layer.

The appropriate precursor and carrier gases are then directed to the deposition chamber (450). According to one exemplary embodiment, the precursor and carrier gases include hydrogen gas for further passivation of the surface.

The nanostructures then spontaneously form on the exposed surface of the substrate. During the growth of the nanostructures, various parameters can be monitored and controlled to produce nanostructures with the desired properties (step 460). By way of example and not limitation, the composition, pressure, and flow rate of the precursor gas could be altered. Additionally, the temperature of the precursor gas and/or substrate could be monitored and controlled.

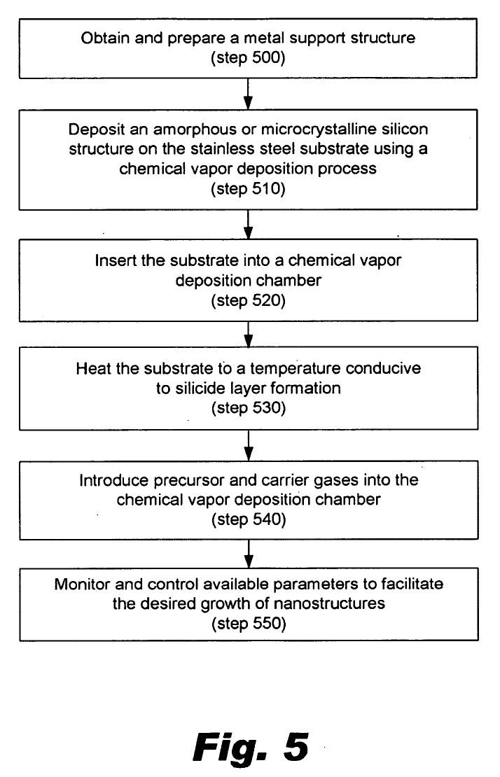

FIG. 5 is a flowchart showing an illustrative process for preparing and growing nanostructures spontaneously on a stainless steel or other metal substrate. In a first step, a stainless steel substrate is obtained and prepared (step 500). It is understood that the metal support structure is not limited to a planar shape but could take the form of a complex geometry with a variety of curves and faces. By way of example and not limitation, the stainless steel or other metal support structure could be formed by lithographic or other processes.

In a second step, amorphous or microcrystalline silicon is deposited on the stainless steel support structure using a chemical vapor deposition process (step 510). The deposition of an additional metal layer is not required because the underlying metal substrate forms the function of the intervening metal layer used in other embodiments.

As discussed with respect to FIG. 4, the prepared substrate is inserted into a chemical vapor deposition chamber (step 520). The substrate temperature is then increased to a level that is conducive to the formation of a silicide layer by a reaction between the metal support structure and the overlying silicon layer (step 530). The appropriate precursor and carrier gases are then directed to the deposition chamber (540), forming nanostructures on the exposed surface of the substrate.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A method of forming nanostructures using catalyst-free epitaxial growth comprising:
depositing a first layer of a non-single crystalline material on a support structure;
heating said support structure and said first layer such that said first layer combines with said support structure or a second layer to form a combined layer, and
growing a nanostructure on said combined layer.

2. The method of claim 1, wherein said heating and said growing are performed within an environmentally controlled chamber.

3. The method of claim 2, wherein said heating further comprises heating said support structure and said first layer to a temperature between 200° C. to 1000° C.

4. The method of claim 3, wherein precursor and carrier gases are passed over said combined layer, thereby growing said nanostructure on said combined layer.

5. The method of claim 4, further comprising monitoring and controlling conditions within said environmental chamber to facilitate desired growth of said nanostructures.

6. The method of claim 1, wherein said first layer is comprised of amorphous, nanocrystalline, or microcrystalline silicon.

7. The method of claim 6, wherein said first layer combines with an adjoining metal to form a silicide.

8. The method of claim 7, wherein said support structure is comprised of a nonmetal material and said second layer is comprised of a metal or transition metal.

9. The method of claim 7, wherein said support structure is comprised of a metal or transition metal, said first layer combining with said support structure to form said silicide.

10. The method of claim 9, wherein said nanostructure is one of: a nanodot, a nanowire, and a nanotube.

11. A hetero-crystalline structure comprising:
a support structure;
a first layer of non-single crystalline material deposited on said support structure and combined with said support structure or a second layer to form a combined layer; and
a nanostructure of a single crystalline material integral to a crystallite of said combined layer.

12. The hetero-crystalline structure of claim 11, wherein said first layer is comprised of amorphous, nanocrystalline, or microcrystalline hydrogenated silicon.

13. The hetero-crystalline structure of claim 12, wherein said first layer is between 10 and 500 nanometers thick.

14. The hetero-crystalline structure of claim 11, wherein said combined layer is a silicide.

15. The hetero-crystalline structure of claim 14, wherein said support structure is nonmetallic and said second layer is a metallic layer; said first layer combining with said second layer to form said silicide.

16. The hetero-crystalline structure of claim 15, wherein said metallic layer is between 10-300 nanometers thick.

17. The hetero-crystalline structure of claim 16, wherein said support structure is metallic, said first layer combining with said support structure to form said silicide.

18. The hetero-crystalline structure-of claim 11, wherein said nanostructure is one of a nanodot, nanotube and a nanowire.

19. The hetero-crystalline structure of claim 18, wherein said silicide is one of titanium silicide, platinum silicide, and tungsten silicide.

20. A hetero-crystalline structure comprising:
a support structure;
an amorphous or microcrystalline hydrogenated silicon layer; said silicon layer being between 10 and 100 nanometers in thickness; said silicon layer combining with an adjoining metal surface to produce a silicide layer, said silicide layer covering at least portion of said support structure; and
a nanostructure of a single crystalline material; said nanostructure being integral to a crystallite within said silicide layer.
